(19) United States
(12) Patent Application Publication
(10) Pub. No.: US 2026/0107783 A1
(43) Pub. Date: Apr. 16, 2026

(54) SEMICONDUCTOR PACKAGE WITH ALIGNMENT MARK AND METHOD OF FABRICATING THE SAME

(71) Applicant: SAMSUNG ELECTRONICS CO., LTD., Suwon-si (KR)

(72) Inventor: Yukyung PARK, Suwon-si (KR)

(73) Assignee: SAMSUNG ELECTRONICS CO., LTD., Suwon-si (KR)

(21) Appl. No.: 19/092,638

(22) Filed: Mar. 27, 2025

(30) Foreign Application Priority Data
Oct. 16, 2024 (KR) 10-2024-0141352

(51) Int. Cl. H01L 23/544; H01L 23/00; H01L 23/31; H01L 23/48; H01L 23/498; H01L 23/538; H01L 25/18

(52) U.S. Cl. CPC H10W 46/00; H10W 20/20; H10W 70/60; H10W 70/611; H10W 70/65; H10W 74/117; H10W 90/00; H10W 90/701; H10W 46/301; H10W 72/242; H10W 74/15; H10W 90/724; H10W 90/734

(57) ABSTRACT

A semiconductor package including: a first semiconductor chip; and a second semiconductor chip on the first semiconductor chip, wherein the first semiconductor chip includes: a first substrate, a first semiconductor device provided on a first surface of the first substrate, a first interconnection layer on the first surface of the first substrate, an insulating layer covering a second surface of the first substrate that is opposite to the first surface of the first substrate, a first via and a second via penetrating the first substrate and the insulating layer in a first direction that is perpendicular to the first surface of the first substrate, and a connection pattern on a surface of the insulating layer and connected to the first via and the second via, wherein a surface of the first via is coplanar with the surface of the insulating layer.

### CROSS-REFERENCE TO RELATED APPLICATIONS

This U.S. non-provisional patent application claims priority under 35 U.S.C. § 119 to Korean Patent Application No. 10-2024-0141352, filed on Oct. 16, 2024, in the Korean Intellectual Property Office, the entire contents of which are hereby incorporated by reference.

### BACKGROUND

The present disclosure relates to a semiconductor package and a method of fabricating the same, and in particular, to a semiconductor package with an alignment mark and a method of fabricating the same.

A semiconductor package is configured to use a semiconductor chip as a part of an electronic product. In general, the semiconductor package may include a substrate (e.g., a printed circuit board (PCB)) and a semiconductor chip, which is mounted on the substrate, and is electrically connected to the substrate using bonding wires to bumps.

With the recent advance in the electronics industry, a demand for high-performance, high-speed, and compact electronic components are increasing. To meet the demand, it is necessary to develop a technology for fabricating a semiconductor device or a semiconductor package having a fast signal transmission property and a small size. For example, it is necessary to develop a technology of packaging a plurality of chips in a single package.

Alignment marks are used to identify process positions during various processes of fabricating the semiconductor package. Thus, an additional process should be performed to form additional alignment mark in a substrate or a semiconductor chip provided in the semiconductor package.

### SUMMARY

One or more embodiments of the present disclosure provides a method of simplifying a process of fabricating a semiconductor package and a semiconductor package fabricated thereby.

A semiconductor package includes: a first semiconductor chip; and a second semiconductor chip on the first semiconductor chip, the first semiconductor chip includes: a first substrate, a first semiconductor device provided on a first surface of the first substrate, a first interconnection layer on the first surface of the first substrate, an insulating layer covering a second surface of the first substrate that is opposite to the first surface of the first substrate, a first via and a second via penetrating the first substrate and the insulating layer in a first direction that is perpendicular to the first surface of the first substrate, and a connection pattern on a surface of the insulating layer and connected to the first via and the second via, wherein a surface of the first via is coplanar with the surface of the insulating layer, and wherein a surface of the second via is located at a level lower than the surface of the insulating layer.

A semiconductor package includes: a first semiconductor chip; and a second semiconductor chip on the first semiconductor chip, wherein the first semiconductor chip includes: a substrate, a semiconductor device provided on a first surface of the substrate, an interconnection layer on the first surface of the substrate, an insulating layer covering a second surface of the substrate that is opposite to the first surface of the substrate; a first via penetrating the substrate and the insulating layer in a first direction that is perpendicular to the first surface of the substrate, a connection pattern on a surface of the insulating layer and connected to the first via, and a passivation layer on the surface of the insulating layer to such that the passivation layer covers at least a portion of the connection pattern, wherein a surface of the first via is placed at a level lower than the surface of the insulating layer, wherein the first semiconductor chip further includes a signal region and a dummy region enclosing the signal region, and wherein the connection pattern includes: a first pattern connected to the first via, and an alignment pattern on the dummy region, the alignment pattern is disconnected from the semiconductor device, and the alignment pattern is placed at a same level as the first pattern.

A semiconductor package includes: a first semiconductor chip; and a second semiconductor chip on the first semiconductor chip, wherein the first semiconductor chip includes: a substrate, a semiconductor device on a first surface of the substrate, an interconnection layer on the first surface of the substrate, an insulating layer covering at least a portion of a second surface of the substrate that is opposite to the first surface of the substrate, a first via and a second via penetrating the substrate and the insulating layer in a first direction that is perpendicular to the first surface of the substrate, a connection pattern on a surface of the insulating layer, the connection pattern including a first pattern connected to the first via and a second pattern connected to the second via, and a passivation layer on the surface of the insulating layer to cover the second pattern and to expose the first pattern, wherein the first via is connected to the semiconductor device, wherein the second via is disconnected from the semiconductor device, and wherein a surface of the second via is located at a level lower than a surface of the insulating layer.

### BRIEF DESCRIPTION OF DRAWINGS

FIG. 1 is a sectional view illustrating a semiconductor package according to one or more embodiments of the present disclosure.

FIG. 2 is an enlarged sectional view illustrating a portion of FIG. 1 according to one or more embodiments of the present disclosure.

FIG. 3 is a plan view illustrating a semiconductor package according to one or more embodiments of the present disclosure.

FIG. 4 is an enlarged sectional view illustrating a portion of FIG. 1 according to one or more embodiments of the present disclosure.

FIG. 5 is a sectional view illustrating a semiconductor package according to one or more embodiments of the present disclosure.

FIG. 6 is an enlarged sectional view illustrating a portion of FIG. 5 according to one or more embodiments of the present disclosure.

FIG. 7 is a sectional view illustrating a semiconductor package according to one or more embodiments of the present disclosure.

FIGS. 8 and 9 are enlarged sectional views illustrating a portion of FIG. 7 according to one or more embodiments of the present disclosure.

FIG. 10 is a sectional view illustrating a semiconductor package according to one or more embodiments of the present disclosure.

FIG. 11 is a sectional view illustrating a semiconductor module according to one or more embodiments of the present disclosure.

FIGS. 12 to 26 are sectional views illustrating a method of fabricating a semiconductor package, according to one or more embodiments of the present disclosure.

### DETAILED DESCRIPTION

Example embodiments of the present disclosure will now be described more fully with reference to the accompanying drawings, in which example embodiments are shown.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

The specification may describe one component or surface being coplanar with another component or surface, respectively. In one or more examples, one component or surface that is coplanar with another component or surface, respectively, may refer to the one component or surface being aligned on the same plane as the another component or surface respectively. In one or more examples, one component or surface that is coplanar with another component or surface, respectively, may refer to the one component or surface being substantially aligned on the same plane as the another component or surface respectively.

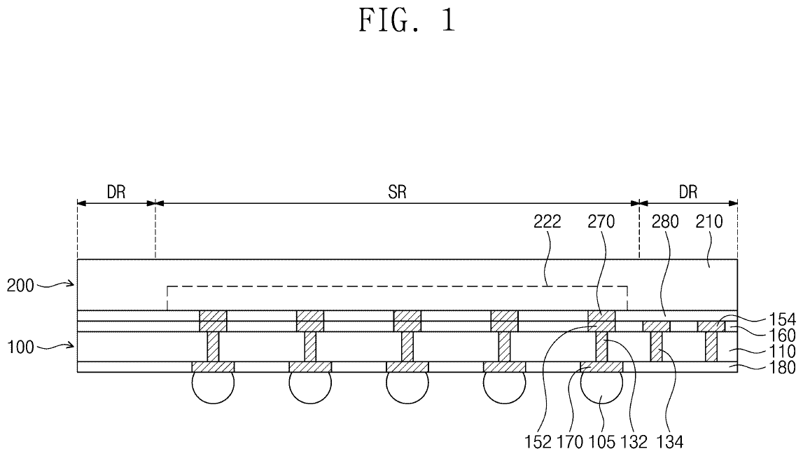

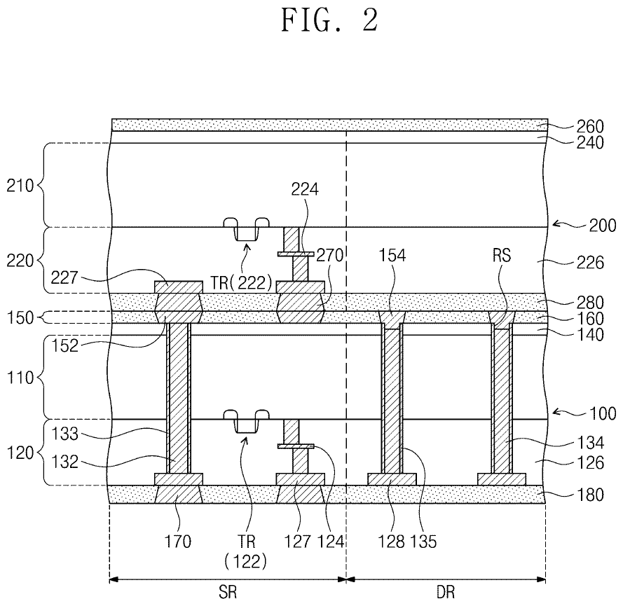

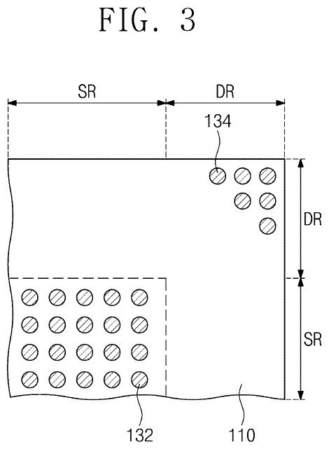

FIG. 1 is a sectional view illustrating a semiconductor package according to one or more embodiments of the present disclosure. FIG. 2 is an enlarged sectional view illustrating a portion of FIG. 1. FIG. 3 is a plan view illustrating a semiconductor package according to one or more embodiments of the present disclosure or illustrating a portion of a first semiconductor chip.

Referring to FIGS. 1 to 3, the semiconductor package may include a first semiconductor chip 100 and a second semiconductor chip 200, which are sequentially stacked.

The first semiconductor chip 100 may include an integrated circuit which is provided therein. For example, the first semiconductor chip 100 may be a wafer-level die, which is formed of a semiconductor material (e.g., silicon (Si)). The first semiconductor chip 100 may include a first substrate 110, a first circuit layer 120, first and second vias 132 and 134, a first insulating layer 140, a first redistribution layer 150, a first upper passivation layer 160, first lower pads 170, and a first lower passivation layer 180.

The first substrate 110 may be provided. The first substrate 110 may include a semiconductor material. For example, the first substrate 110 may be a single crystalline silicon substrate, or any other suitable material known to one of ordinary skill in the art, for example, a low-k dielectric material such as silicon oxide (SiO₂), not being limited thereto.

The first substrate 110 may have a signal region SR and a dummy region DR. When viewed in a plan view, the signal region SR may be placed in a center portion of the first substrate 110, and the dummy region DR may be provided to enclose the signal region SR. The signal region SR may be a region, which is provided on the center portion of the first substrate 110 and is provided with semiconductor devices of the first semiconductor chip 100. The dummy region DR may be an edge region of the first substrate 110, on which the semiconductor devices are not provided. According to one or more embodiments, the dummy region DR may be a region, on which an alignment key for the alignment between the semiconductor chips 100 and 200 is provided. The first substrate 110 may have a top surface and a bottom surface, which are opposite to each other. The bottom surface of the first substrate 110 may be a front surface of the first substrate 110, and the top surface of the first substrate 110 may be a rear surface of the first substrate 110. In one or more examples, the front surface of the first substrate 110 may be defined as a surface of the first substrate 110, on which semiconductor devices, interconnection lines, or pads are formed or provided, and the rear surface of the first substrate 110 may be defined as a surface that is opposite to the front surface. For example, the bottom surface of the first semiconductor chip 100 may be an active surface.

The first semiconductor chip 100 may have the first circuit layer 120 provided on the bottom surface of the first substrate 110. The first circuit layer 120 may include a first semiconductor device 122 and a first device interconnection portion 124.

The first semiconductor device 122 may include transistors TR, which are provided in the signal region SR of the first substrate 110 and on the bottom surface of the first substrate 110. In one or more embodiments, the transistors TR may include source and drain electrodes formed in a lower portion of the first substrate 110, a gate electrode disposed on the bottom surface of the first substrate 110, and a gate insulating layer interposed between the first substrate 110 and the gate electrode. FIG. 2 illustrates an example in which one transistor TR is provided, but the present disclosure is not limited to this example. The first semiconductor device 122 may include a plurality of transistors TR. The first semiconductor device 122 may include a logic circuit or a memory circuit. In one or more examples, the first semiconductor device 122 may include a device isolation pattern, which is formed in the signal region SR and in the bottom surface of the first substrate 110, and may be used to form a logic cell or a plurality of memory cells. In one or more embodiments, the first semiconductor device 122 may include a passive device (e.g., a capacitor). The first semiconductor device 122 may not be disposed on the dummy region DR of the first substrate 110.

The bottom surface of the first substrate 110 may be covered with a first device interlayer insulating layer 126. The first device interlayer insulating layer 126 may cover the first semiconductor device 122 on the signal region SR. In one or more examples, the first device interlayer insulating layer 126 may cover the first semiconductor device 122. For example, the first semiconductor device 122 may not be exposed by the first device interlayer insulating layer 126. The first device interlayer insulating layer 126 may include at least one of, for example, silicon oxide (SiO), silicon nitride (SiN), or silicon oxynitride (SiON). In one or more examples, the first device interlayer insulating layer 126 may include a low-k dielectric material. The first device interlayer insulating layer 126 may have a single- or multi-layered structure. In the case where the first device interlayer insulating layer 126 is provided in the multi-layered structure, each of interconnection layers to be described below may be provided in one insulating layer, and an etch stop layer may be interposed between the insulating layers. For example, the etch stop layer may be provided on a bottom surface of at least one of the insulating layers. The etch stop layer may be formed of or include at least one of, for example, silicon nitride (SiN), silicon oxynitride (SiON), or silicon carbonitride (SiCN).

The first device interconnection portion 124 connected to the transistors TR may be provided on the signal region SR and in the first device interlayer insulating layer 126. The first device interconnection portion 124 may include signal line patterns, which are provided in the first device interlayer insulating layer 126. For example, the signal line patterns may include redistribution patterns for the horizontal interconnection and via patterns for the vertical interconnection. The first device interconnection portion 124 may be provided to vertically penetrate the first device interlayer insulating layer 126 and may be connected to one of the source, drain, or gate electrodes of the transistors TR. In one or more examples, the first device interconnection portion 124 may be connected to various devices of the first semiconductor device 122. The first device interconnection portion 124 may be located between top and bottom surfaces of the first device interlayer insulating layer 126. The first device interconnection portion 124 may not be placed on the dummy region DR. The first device interconnection portion 124 may include, for example, copper (Cu) or tungsten (W).

FIG. 2 illustrates an example, in which one interconnection layer is provided in the first device interlayer insulating layer 126, but the present disclosure is not limited to this example. In another embodiment, a plurality of interconnection layers may be provided in the first device interlayer insulating layer 126. In one or more examples, an interconnection layer may be a pattern of metal and insulator films that connect components on a semiconductor chip. Interconnection layers may be built on top of a wafer in multiple levels, with vias forming connections between levels. Hereinafter, the present disclosure will be described with reference to the embodiment of FIG. 2.

First and second lower connection patterns 127 and 128 may be provided in a lower portion of the first device interlayer insulating layer 126. Bottom surfaces of the first and second lower connection patterns 127 and 128 may be exposed to the outside of the first device interlayer insulating layer 126 near the bottom surface of the first device interlayer insulating layer 126. The bottom surfaces of the first and second lower connection patterns 127 and 128 may be coplanar with the bottom surface of the first device interlayer insulating layer 126. The first lower connection patterns 127 may be disposed on the signal region SR. At least one of the first lower connection patterns 127 may be connected to the first device interconnection portion 124. The second lower connection patterns 128 may be disposed on the dummy region DR. The second lower connection patterns 128 may be electrically disconnected from the first semiconductor device 122 and the first device interconnection portion 124. The second lower connection patterns 128 may not be provided, if necessary. The first and second lower connection patterns 127 and 128 may include, for example, copper (Cu), tungsten (W), or any other suitable material known to one of ordinary skill in the art.

The first insulating layer 140 may be provided on the top surface of the first substrate 110. The first insulating layer 140 may cover the top surface of the first substrate 110. The first insulating layer 140 may include at least one of, for example, silicon oxide (SiO), silicon nitride (SiN), and silicon oxynitride (SiON). The first insulating layer 140 may have a single- or multi-layered structure.

First vias 132 may be provided to vertically penetrate the first substrate 110 and may be connected to the first lower connection patterns 127. The first vias 132 may be patterns for a vertical interconnection. In one or more examples, the first vias 132 may be electrically connected to the semiconductor devices, which are formed on the first substrate 110, and may be used for the vertical interconnection of the semiconductor devices, in the first semiconductor chip 100. As shown in FIG. 3, the first vias 132 may be arranged on the signal region SR to form a plurality of rows and a plurality of columns. However, the present disclosure is not limited to this example, and in one or more embodiments, the planar placement of the first vias 132 may be variously changed, depending on the interconnection layout in the first semiconductor chip 100 or other requirements. Some of the first vias 132 may be provided on the signal region SR to vertically penetrate the first device interlayer insulating layer 126 and may be coupled to top surfaces of some of the first lower connection patterns 127.

The second vias 134 may be provided to vertically penetrate the first substrate 110 and may be connected to the second lower connection patterns 128. The second vias 134 may be patterns, which are used as an alignment key for placing elements in the first semiconductor chip 100 and for aligning the first and second semiconductor chips 100 and 200 to each other, during the fabrication process of the semiconductor package. In one or more examples, as shown in FIG. 3, the second vias 134 may be arranged to form a specific pattern for the inspection of the horizontal position and rotation of the first semiconductor chip 100 on the dummy region DR. However, the present disclosure is not limited to this example, and in one or more embodiments, the planar placement of the second vias 134 may be changed to various patterns that can be used as the alignment key. The second vias 134 may be electrically disconnected from the first semiconductor device 122 and the first device interconnection portion 124. The second vias 134 may be provided on the dummy region DR to vertically penetrate the first device interlayer insulating layer 126 and to be in contact with top surfaces of the second lower connection patterns 128.

The first vias 132 and the second vias 134 may be provided to vertically penetrate the first device interlayer insulating layer 126, the first substrate 110, and the first insulating layer 140 and may be exposed to a region on a top surface of the first insulating layer 140. Top surfaces of the first vias 132 may be substantially coplanar with the top surface of the first insulating layer 140 and may be substantially flat. In one or more examples, the top surfaces of the first vias 132 may be located at the same vertical level as the top surface of the first insulating layer 140. Top surfaces of the second vias 134 may be located at a vertical level lower than the top surface of the first insulating layer 140. For example, the top surfaces of the second vias 134 may be formed to have a recess region RS, which is recessed from the top surface of the first insulating layer 140 toward the first substrate 110. The first vias 132 and the second vias 134 may include, for example, tungsten (W).

In one or more embodiments, since the second vias 134, which are formed during the process of forming the first vias 132, are used as the alignment key, it may be unnecessary to perform an additional process of forming the alignment key. This will be described in more detail with reference to a fabrication method below. In addition, since the top surfaces of the second vias 134 are provided at a low level, the recess regions RS may be formed on the second vias 134. The recess regions RS may form an intaglio alignment key, thereby improving the visibility or sensitivity of the alignment key during the alignment process. For example, the recess regions RS may be used to align a semiconductor chip precisely on a substrate.

First and second seed layers 133 and 135 may be provided between the first substrate 110 and the first and second vias 132 and 134.

The first seed layers 133 may be formed to enclose outer circumferential surfaces of the first vias 132. The first seed layers 133 may separate the first vias 132 from the first substrate 110, the first device interlayer insulating layer 126, and the first insulating layer 140. Top surfaces of the first seed layers 133 may be located at the same vertical level as the top surface of the first vias 132. The top surfaces of the first seed layers 133 may be substantially coplanar with the top surfaces of the first vias 132 and may be substantially flat. Bottom surfaces of the first seed layers 133 may be located at the same vertical level as bottom surfaces of the first vias 132. The bottom surfaces of the first seed layers 133 may be substantially coplanar with the bottom surfaces of the first vias 132 and may be substantially flat. The first seed layers 133 may be in contact with the first lower connection patterns 127. In another embodiment, the first seed layers 133 may cover bottom surfaces of the first vias 132, unlike that shown in FIG. 2. In one or more examples, a seed layer may be a thin layer of material that's deposited on a surface to promote the growth of a subsequent layer. Seed layers can be used to improve the crystallinity of a layer, which can lead to better performance in optoelectronic devices.

The second seed layers 135 may be formed to enclose outer circumferential surfaces of the second vias 134. The second seed layers 135 may separate the second vias 134 from the first substrate 110, the first device interlayer insulating layer 126, and the first insulating layer 140. Top surfaces of the second seed layers 135 may be located at vertical levels different from the top surfaces of the second vias 134. For example, the top surfaces of the second seed layers 135 may be located at a vertical level higher than the top surfaces of the second vias 134. The top surfaces of the second seed layers 135 may be substantially coplanar with the top surface of the first insulating layer 140 and may be substantially flat. Inner side surfaces of the second seed layers 135, which are exposed by the second vias 134, may correspond to inner side surfaces of the recess regions RS provided on the second vias 134. Bottom surfaces of the second seed layers 135 may be located at the same vertical level as the bottom surfaces of the second vias 134. The bottom surfaces of the second seed layers 135 may be substantially coplanar with the bottom surfaces of the second vias 134 and may be substantially flat. The second seed layers 135 may be in contact with the second lower connection patterns 128. In another embodiment, unlike the structure illustrated in FIG. 2, the second seed layers 135 may cover the bottom surfaces of the second vias 134.

The first seed layers 133 and the second seed layers 135 may be formed of or include a metallic material (e.g., gold (Au)). In another embodiment, the first seed layers 133 and the second seed layers 135 may not be provided, if necessary.

The first lower pads 170 may be disposed on the first device interlayer insulating layer 126. The first lower pads 170 may be provided on the signal region SR. The first lower pads 170 may be disposed on bottom surfaces of the first lower connection patterns 127. The first lower pads 170 may be coupled to bottom surfaces of the first lower connection patterns 127. In one or more examples, the first lower connection patterns 127 may be under-pad patterns of the first lower pads 170. The first lower pads 170 may have a plate shape. In another embodiment, each of the first lower pads 170 may have a pattern including a via portion and a pad portion, which are sequentially stacked to form a single object, and having an inverted T-shaped section. The first lower pads 170 may include a metallic material. For example, the first lower pads 170 may be formed of or include copper (Cu).

The first lower passivation layer 180 may be disposed on the first device interlayer insulating layer 126. The first lower passivation layer 180 may be provided on a bottom surface of the first device interlayer insulating layer 126 to cover the first and second lower connection patterns 127 and 128. The first lower passivation layer 180 may be provided on the bottom surface of the first device interlayer insulating layer 126 to enclose the first lower pads 170. The first lower pads 170 may be exposed by the first lower passivation layer 180. For example, the first lower passivation layer 180 may be provided to enclose the first lower pads 170 and may not cover the first lower pads 170, when viewed in a plan view. A bottom surface of the first lower passivation layer 180 may be coplanar with bottom surfaces of the first lower pads 170. As understood by one of ordinary skill in the art, a passivation layer may be a dielectric material that protects the semiconductor from environmental factors and stabilizes the semiconductor's surface. The first lower passivation layer 180 may be formed of or include at least one of silicon nitride (SiN), silicon oxide (SiO), silicon oxycarbide (SiOC), silicon oxynitride (SiON), or silicon carbonitride (SiCN).

The first lower pads 170 may be outer pads, which are used to mount the semiconductor package. For example, outer terminals 105 may be provided on the first lower pads 170. The outer terminals 105 may be coupled to the first lower pads 170. The outer terminals 105 may include solder balls or solder bumps, and the semiconductor package may be classified into a ball grid array (BGA) structure, a fine ball-grid array (FBGA) structure, or a land grid array (LGA) structure, depending on the kind and arrangement of the outer terminals 105.

The first redistribution layer 150 may be disposed on the top surface of the first insulating layer 140. The first redistribution layer 150 may include first and second upper connection patterns 152 and 154. The first and second upper connection patterns 152 and 154 may be redistribution patterns or pad patterns, which are used for the connection of the first and second vias 132 and 134. Some of the first upper connection patterns 152 may serve as upper pads of the first semiconductor chip 100, which are provided to mount the second semiconductor chip 200 on the first semiconductor chip 100. In one or more embodiments, some of the first upper connection patterns 152 may include redistribution patterns connecting the first vias 132 to the upper pads. As understood by one of ordinary skill in the art, a redistribution pattern may be a network of metal traces that reroute connections on a chip. The pattern may be created using photolithography and electroplating.

The first upper connection patterns 152 may be disposed on the signal region SR. Some of the first upper connection patterns 152 may be connected to the first vias 132. For example, some of the first vias 132 may be provided to vertically penetrate the first substrate 110 and may be coupled to bottom surfaces of the first upper connection patterns 152. The bottom surfaces of the first upper connection patterns 152 may be flat. The first upper connection patterns 152 may not be placed on the dummy region DR. The first upper connection patterns 152 may include, for example, copper (Cu) or tungsten (W).

The second upper connection patterns 154 may be disposed on the dummy region DR. The second upper connection patterns 154 may be provided at the same vertical level as the first upper connection patterns 152 and may include the same material as the first upper connection patterns 152. For example, the first and second upper connection patterns 152 and 154 may be patterns, which are formed by patterning a single metal layer. The second upper connection patterns 154 may be electrically disconnected from the first semiconductor device 122 and the first device interconnection portion 124. In addition, the second upper connection patterns 154 may be electrically disconnected from other devices and interconnection lines in the semiconductor package. In one or more examples, the second upper connection patterns 154 and the second lower connection patterns 128 may be electrically floated in the semiconductor package. The second upper connection patterns 154 may be connected to the second vias 134, respectively. For example, some of the second vias 134 may be provided to vertically penetrate the first substrate 110 and may be coupled to bottom surfaces of the second upper connection patterns 154. In one or more examples, since the recess regions RS are provided on the second vias 134, each of the second upper connection patterns 154 may have a protruding portion, which is extended into the first insulating layer 140 to fill the recess regions RS. The protruding portions of the second upper connection patterns 154 may be in contact with the top surfaces of the second vias 134. The second upper connection patterns 154 may not be disposed on the signal region SR of the first substrate 110. The second upper connection patterns 154 may include, for example, copper (Cu) or tungsten (W).

Since the second upper connection patterns 154 are disposed on the second vias 134 to form the same arrangement as the second vias 134, the second upper connection patterns 154 may be patterns, which are used as an alignment key for placing elements in the first semiconductor chip 100 and for aligning the first and second semiconductor chips 100 and 200 to each other, during the fabrication process of the semiconductor package.

In one or more embodiments, since the second upper connection patterns 154, which are formed during the process of forming the first upper connection patterns 152, are used as the alignment key, an additional process may not be required to form the alignment key, thereby improving the efficiency of the semiconductor manufacturing process. In addition, even when the second vias 134 are veiled in a subsequent process after the formation of the second vias 134, the second upper connection patterns 154 may be used as the alignment key. These advantageous features will be described in more detail with reference to a fabrication method below.

The first upper passivation layer 160 may be disposed on the first insulating layer 140. The first upper passivation layer 160 may enclose the first and second upper connection patterns 152 and 154, on the top surface of the first insulating layer 140. The first and second upper connection patterns 152 and 154 may be exposed by the first upper passivation layer 160. For example, when viewed in a plan view, the first upper passivation layer 160 may enclose the first and second upper connection patterns 152 and 154 and may not cover the first and second upper connection patterns 152 and 154. A top surface of the first upper passivation layer 160 may be coplanar with the top surfaces of the first and second upper connection patterns 152 and 154. The first upper passivation layer 160 may include at least one of silicon nitride (SiN), silicon oxide (SiO), silicon oxycarbide (SiOC), silicon oxynitride (SiON), or silicon carbonitride (SiCN). The first upper passivation layer 160 may have a single- or multi-layered structure.

The second semiconductor chip 200 may have a structure that is substantially similar to the first semiconductor chip 100. For example, the second semiconductor chip 200 may include a second substrate 210, a second circuit layer 220, second lower pads 270, and a second lower passivation layer 280. The second semiconductor chip 200 may not have a second via and a second redistribution layer. However, the present disclosure is not limited to this example. In another embodiment, the second semiconductor chip 200 may include at least one of the second via and the second redistribution layer.

The second substrate 210 may be provided. The second substrate 210 may include a semiconductor material, which may be the same as or similar to the material forming the first substrate 110.

The second circuit layer 220 may be provided on the bottom surface of the second substrate 210. The second circuit layer 220 may include a second semiconductor device 222 and a second device interconnection portion 224. The second semiconductor device 222 may include transistors TR, which are provided in the signal region SR of the second substrate 210 and on the bottom surface of the second substrate 210. The second semiconductor device 222 may not be disposed on the dummy region DR of the second substrate 210. The bottom surface of the second substrate 210 may be covered with a second device interlayer insulating layer 226. The second device interlayer insulating layer 226 may be provided on the signal region SR to cover the second semiconductor device 222. The second device interconnection portion 224, which are connected to the transistors TR, may be provided on the signal region SR and in the second device interlayer insulating layer 226.

Third lower connection patterns 227 may be provided in a lower portion of the second device interlayer insulating layer 226. Bottom surfaces of the third lower connection patterns 227 may be exposed to a region on the bottom surface of the second device interlayer insulating layer 226. The third lower connection patterns 227 may be disposed on the signal region SR. The third lower connection patterns 227 may be connected to the second device interconnection portion 224.

The second lower pads 270 may be disposed on the second device interlayer insulating layer 226. The second lower pads 270 may be disposed on the bottom surfaces of the third lower connection patterns 227. The second lower pads 270 may be electrically connected to the second semiconductor device 222. For example, as shown in FIG. 2, the second lower pads 270 may be provided on the signal region SR and may be coupled to bottom surfaces of the third lower connection patterns 227. For example, the third lower connection patterns 227 may be under-pad patterns of the second lower pads 270. The third lower connection patterns 227 may electrically connect the second semiconductor device 222 to the second lower pads 270.

The second lower passivation layer 280 may be disposed on the second device interlayer insulating layer 226. The second lower passivation layer 280 may be provided on the bottom surface of the second device interlayer insulating layer 226 to cover the third lower connection patterns 227. The second lower passivation layer 280 may be provided on the bottom surface of the second device interlayer insulating layer 226 to enclose the second lower pads 270. The second lower pads 270 may be exposed by the second lower passivation layer 280. For example, the second lower passivation layer 280 may enclose the second lower pads 270 in a plan view but may not cover the second lower pads 270. A bottom surface of the second lower passivation layer 280 may be coplanar with bottom surfaces of the second lower pads 270. The second lower passivation layer 280 may be formed of or include at least one of silicon nitride (SiN), silicon oxide (SiO), silicon oxycarbide (SiOC), silicon oxynitride (SiON), or silicon carbonitride (SiCN).

A second insulating layer 240 may be provided on the top surface of the second substrate 210. The second insulating layer 240 may cover the top surface of the second substrate 210. The second insulating layer 240 may include at least one of, for example, silicon oxide (SiO), silicon nitride (SiN), or silicon oxynitride (SiON). The second insulating layer 240 may not be provided, if necessary.

A second upper passivation layer 260 may be disposed on the second insulating layer 240. The second upper passivation layer 260 may be formed of or include at least one of silicon nitride (SiN), silicon oxide (SiO), silicon oxycarbide (SiOC), silicon oxynitride (SiON), or silicon carbonitride (SiCN). The second upper passivation layer 260 may not be provided, if necessary.

The second semiconductor chip 200 may be disposed on the first semiconductor chip 100. On the signal region SR, the first upper connection patterns 152 of the first semiconductor chip 100 may be vertically aligned to the second lower pads 270 of the second semiconductor chip 200. On the dummy region DR, the second lower passivation layer 280 may cover the second upper connection patterns 154. The first and second semiconductor chips 100 and 200 may be in contact with each other.

At an interface of the first and second semiconductor chips 100 and 200, the first upper passivation layer 160 of the first semiconductor chip 100 may be bonded to the second lower passivation layer 280 of the second semiconductor chip 200. In one or more examples, the first upper passivation layer 160 and the second lower passivation layer 280 may form a hybrid bonding structure of oxide, nitride, or oxynitride. In the present specification, the hybrid bonding structure may refer to a bonding structure which is formed by two materials, which are of the same kind and are fused at an interface therebetween. For example, the first upper passivation layer 160 and the second lower passivation layer 280, which are bonded to each other, may form a continuous structure, and there may be no visible or observable interface between the first upper passivation layer 160 and the second lower passivation layer 280. For example, the first upper passivation layer 160 and the second lower passivation layer 280 may be formed of the same material, and there may be no interface between the first upper passivation layer 160 and the second lower passivation layer 280. In one or more examples, the first upper passivation layer 160 and the second lower passivation layer 280 may be provided as a single object. For example, the first upper passivation layer 160 and the second lower passivation layer 280 may be bonded to form a single object. However, the present disclosure is not limited to this example. The first upper passivation layer 160 and the second lower passivation layer 280 may be formed of different materials. The first upper passivation layer 160 and the second lower passivation layer 280 may not have a continuous structure, and there may be a visible or observable interface between the first upper passivation layer 160 and the second lower passivation layer 280. In one or more examples, hybrid bonding may be a bond that combine a dielectric bond (e.g., SiOx) with embedded metal (e.g., Cu) to form interconnections.

The first semiconductor chip 100 may be connected to the second semiconductor chip 200. In one or more examples, the first and second semiconductor chips 100 and 200 may be in contact with each other. At the interface of the first and second semiconductor chips 100 and 200, the first upper connection patterns 152 of the first semiconductor chip 100 may be bonded to the second lower pads 270 of the second semiconductor chip 200. In one or more examples, the first upper connection patterns 152 and the second lower pads 270 may form an inter-metal hybrid bonding structure. For example, the first upper connection patterns 152 and the second lower pads 270, which are bonded to each other, may form a continuous structure, and there may be no visible or observable interface between the first upper connection patterns 152 and the second lower pads 270. For example, the first upper connection patterns 152 and the second lower pads 270 may be formed of the same material, and in this case, there may be no interface between the first upper connection patterns 152 and the second lower pads 270. In one or more examples, the first upper connection patterns 152 and the second lower pads 270 may be provided as a single object. For example, the first upper connection patterns 152 and the second lower pads 270 may be bonded to form a single object.

In the description of the embodiments to be explained below, an element previously described with reference to FIGS. 1 to 3 may be identified by the same reference number without repeating an overlapping description thereof, for concise description.

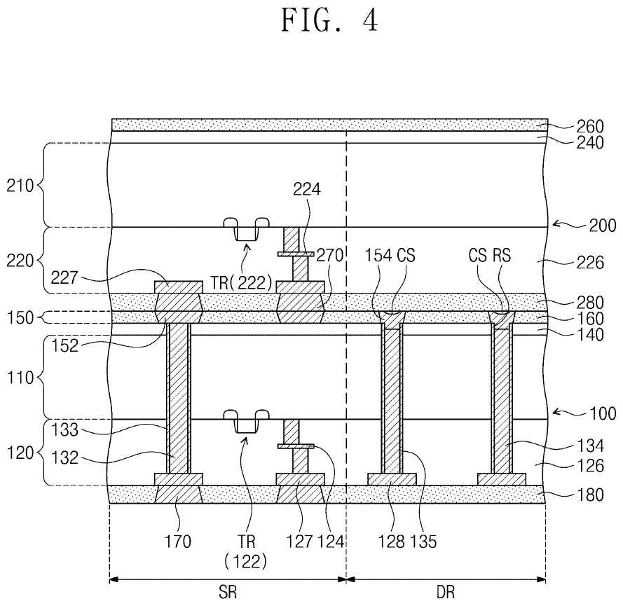

FIG. 4 is an enlarged sectional view illustrating a portion of FIG. 1.

Referring to FIG. 4, the second upper connection pattern 154 may have a top surface that is exposed to the outside of the first upper passivation layer 160 near the top surface of the first upper passivation layer 160. The top surface of the second upper connection patterns 154 may have a recessed portion CS. In one or more embodiments, at least a portion of the top surface of the second upper connection pattern 154 may be a concave surface, which is recessed toward the second via 134. FIG. 4 illustrates an example, in which the recessed portion CS is formed in a portion of the top surface of the second upper connection pattern 154, but the present disclosure is not limited to this example. In another embodiment, the entire top surface of the second upper connection patterns 154 may be a concave surface.

In one or more embodiments, the recessed portion CS may be provided on the top surface of the second upper connection patterns 154. The recessed portions CS may form an intaglio alignment key, thereby improving the visibility or sensitivity of the alignment key during the alignment process.

At an interface of the first and second semiconductor chips 100 and 200, the first upper passivation layer 160 of the first semiconductor chip 100 may be bonded to the second lower passivation layer 280 of the second semiconductor chip 200. On the dummy region DR, the second lower passivation layer 280 may cover the second upper connection patterns 154. Due to the recessed portions CS, a portion of the top surface of the second upper connection patterns 154 may be spaced apart from the second lower passivation layer 280.

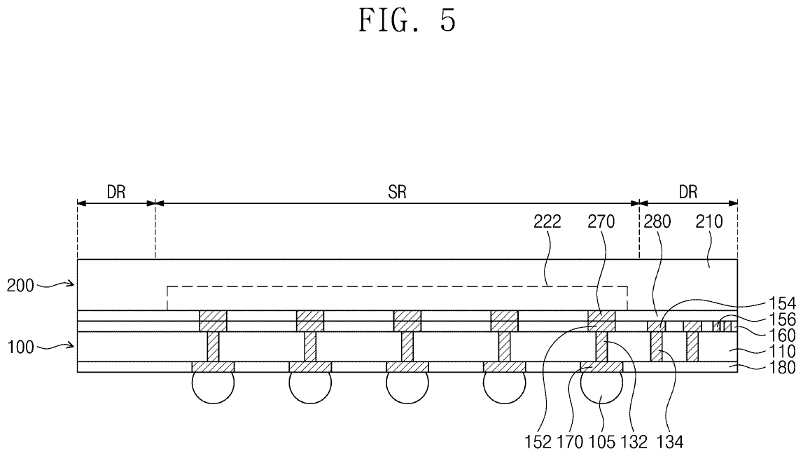

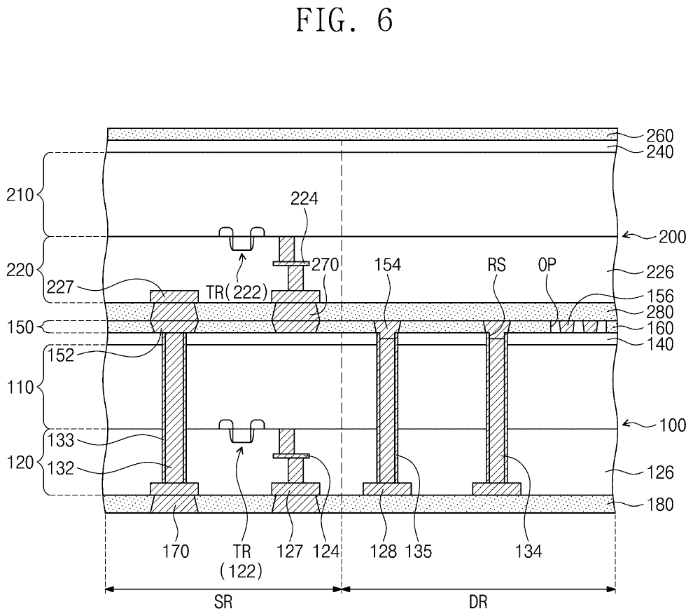

FIG. 5 is a sectional view illustrating a semiconductor package according to one or more embodiments of the present disclosure. FIG. 6 is an enlarged sectional view illustrating a portion of FIG. 5.

Referring to FIGS. 5 and 6, the first redistribution layer 150 may be disposed on the top surface of the first insulating layer 140 of the first semiconductor chip 100. The first redistribution layer 150 may further include third upper connection patterns 156, in addition to the first and second upper connection patterns 152 and 154.

The third upper connection patterns 156 may be disposed on the dummy region DR. The third upper connection patterns 156 may be alignment patterns, which are used as an alignment key for the alignment of the first and second semiconductor chips 100 and 200. In one or more examples, the third upper connection patterns 156 may be arranged to form a specific pattern for the inspection of the horizontal position and rotation of the first semiconductor chip 100 on the dummy region DR. The third upper connection patterns 156 may be provided at the same vertical level as the first and second upper connection patterns 152 and 154 and may include the same material as the first and second upper connection patterns 152 and 154. For example, the first to third upper connection patterns 152, 154, and 156 may be patterns, which are formed by patterning a single metal layer. The third upper connection patterns 156 may be electrically disconnected from the first semiconductor device 122 and the first device interconnection portion 124. In addition, the third upper connection patterns 156 may be electrically disconnected from other devices and interconnection lines in the semiconductor package. In one or more examples, the third upper connection patterns 156 and the second lower connection patterns 128 may be electrically floated in the semiconductor package. The third upper connection patterns 156 may be spaced apart from the second vias 134. For example, when viewed in a plan view, the third upper connection patterns 156 may be placed between the second vias 134 and a side surface of the first substrate 110. For example, the second vias 134 may be placed between the third upper connection patterns 156 and the signal region SR. The third upper connection patterns 156 may be spaced apart from the first substrate 110 by the first insulating layer 140. The third upper connection patterns 156 may not be disposed on the signal region SR of the first substrate 110. The third upper connection patterns 156 may include, for example, copper (Cu) or tungsten (W). In one or more examples, the third upper connection pattern 156 may include two vertical pillars with a gap therebetween.

The first upper passivation layer 160 may be disposed on the first insulating layer 140. The first upper passivation layer 160 may be provided on the top surface of the first insulating layer 140 to enclose the first and second upper connection patterns 152 and 154. The first and second upper connection patterns 152 and 154 may be exposed by the first upper passivation layer 160. For example, when viewed in a plan view, the first upper passivation layer 160 may enclose the first and second upper connection patterns 152 and 154 and may not cover the first and second upper connection patterns 152 and 154. The top surface of the first upper passivation layer 160 may be coplanar with the top surfaces of the first and second upper connection patterns 152 and 154.

The first upper passivation layer 160 may have an opening OP. The opening OP may be provided to vertically penetrate the first upper passivation layer 160 and to expose the top surface of the first insulating layer 140.

The third upper connection patterns 156 may be placed within the opening OP. The third upper connection patterns 156 may be spaced apart from the first upper passivation layer 160. In one or more examples, the third upper connection patterns 156 may be spaced apart from an inner side surface of the opening OP of the first upper passivation layer 160 (FIG. 6). Thus, the third upper connection patterns 156 may not be veiled by the first upper passivation layer 160 and may be exposed to the outside.

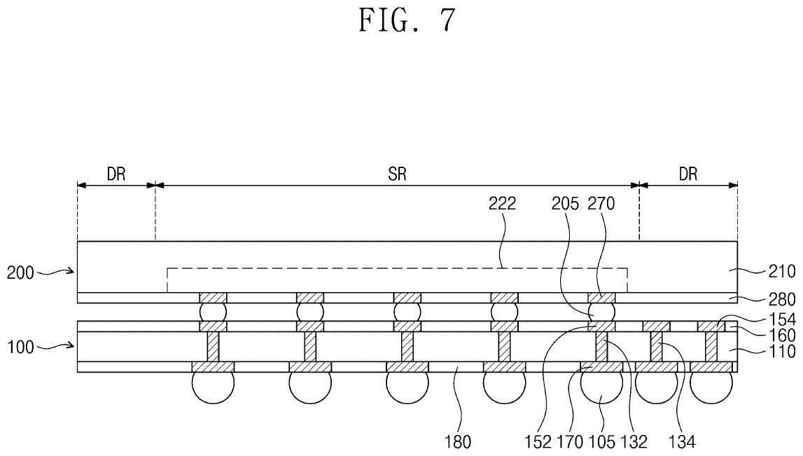

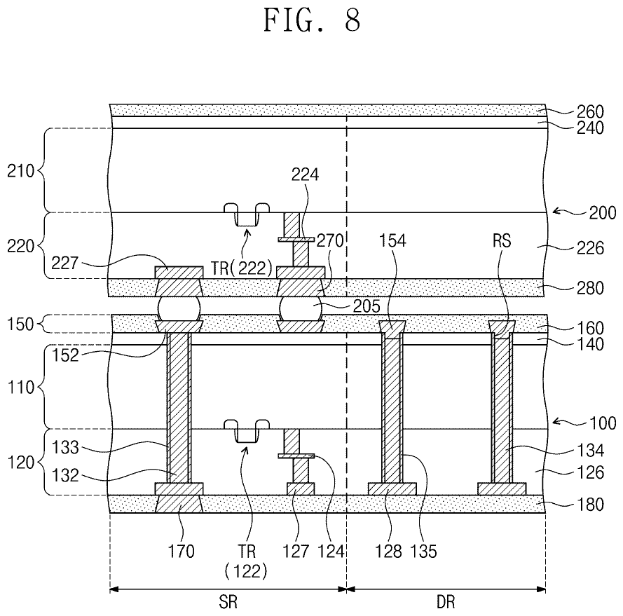

FIG. 7 is a sectional view illustrating a semiconductor package according to one or more embodiments of the present disclosure. FIGS. 8 and 9 are enlarged sectional views illustrating a portion of FIG. 7.

Referring to FIGS. 7 and 8, the first upper passivation layer 160 may be disposed on the first insulating layer 140. The first upper passivation layer 160 may be provided on the top surface of the first insulating layer 140 to cover the first and second upper connection patterns 152 and 154. For example, the top surface of the first upper passivation layer 160 may be located at a level higher than the top surfaces of the first and second upper connection patterns 152 and 154. The second upper connection patterns 154 may be buried by the first upper passivation layer 160. The first upper passivation layer 160 may have recesses exposing the first upper connection patterns 152.

The second semiconductor chip 200 may be disposed on the first semiconductor chip 100. On the signal region SR, the first upper connection patterns 152 of the first semiconductor chip 100 may be vertically aligned to the second lower pads 270 of the second semiconductor chip 200. The first and second semiconductor chips 100 and 200 may be spaced apart from each other.

Intermediate connection terminals 205 may be provided on the second lower pads 270 of the second semiconductor chip 200. The intermediate connection terminals 205 may be coupled to the second lower pads 270. The intermediate connection terminals 205 may include solder balls or solder bumps.

The second semiconductor chip 200 may be mounted on the first semiconductor chip 100. In one or more examples, the intermediate connection terminals 205 may be disposed between the first upper connection patterns 152 of the first semiconductor chip 100 and the second lower pads 270 of the second semiconductor chip 200. The intermediate connection terminals 205 may connect the first upper connection patterns 152 to the second lower pads 270.

In another embodiment, as shown in FIG. 9, the first redistribution layer 150 of the first semiconductor chip 100 may further include the third upper connection patterns 156, in addition to the first and second upper connection patterns 152 and 154, as described with reference to FIG. 6. The first upper passivation layer 160 may have the opening OP.

The opening OP may be formed to vertically penetrate the first upper passivation layer 160 and to expose the top surface of the first insulating layer 140. The third upper connection patterns 156 may be placed within the opening OP. The third upper connection patterns 156 may not be veiled by the first upper passivation layer 160 and may be exposed to the outside.

In one or more embodiments, even when the second upper connection patterns 154 are veiled by the first upper passivation layer 160, the third upper connection patterns 156 may be used as an alignment key. For example, before second upper connection patterns 154 are veiled by the first upper passivation layer 160, the second upper connection patterns 154 may be used as an alignment key during a fabrication process.

The second semiconductor chip 200 may be mounted on the first semiconductor chip 100. The intermediate connection terminals 205 may connect the first upper connection patterns 152 to the second lower pads 270.

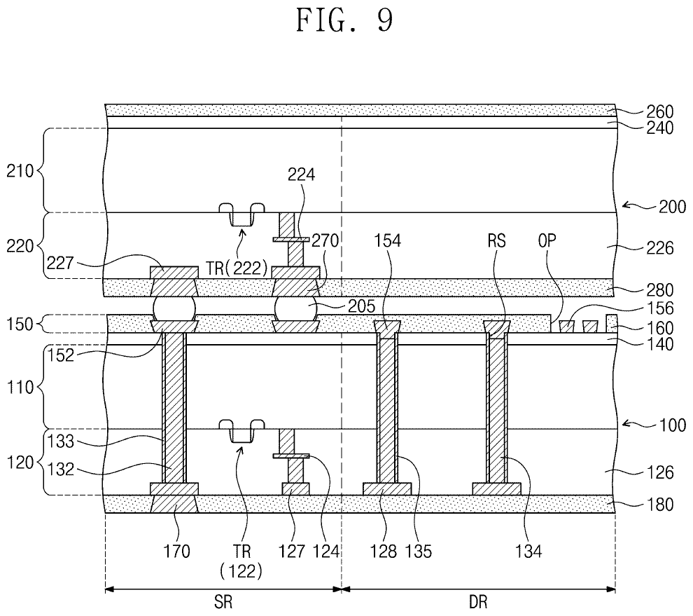

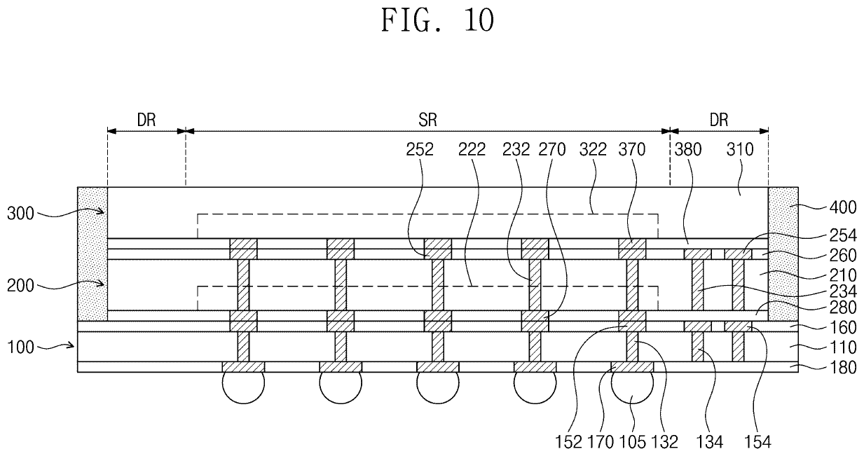

FIG. 10 is a sectional view illustrating a semiconductor package according to one or more embodiments of the present disclosure. In the embodiment of FIG. 10, the names of the first to third semiconductor chips are assigned in the order they are stacked for convenience in description, and the name of the first and second semiconductor chips do not necessarily indicate that they have the same structure as the first and second semiconductor chips described with reference to FIG. 1, even though the names are identical.

Referring to FIG. 10, the first semiconductor chip 100 may be substantially the same as or similar to the first semiconductor chip 100 described with reference to FIG. 1. The first semiconductor chip 100 may be a logic chip. In one or more examples, the first semiconductor chip 100 may be a memory chip or may be a semiconductor component (e.g., a buffer chip), in which an electronic element (e.g., a transistor) is not provided.

The second semiconductor chip 200 may be provided. A width of the second semiconductor chip 200 may be smaller than a width of the first semiconductor chip 100. The second semiconductor chip 200 may be similar to the first semiconductor chip 100 described with reference to FIG. 1. For example, the second semiconductor chip 200 may include the second substrate 210, the second semiconductor device 222 formed in the second substrate 210, the second lower pads 270, the second lower passivation layer 280, and the second upper passivation layer 260.

The second semiconductor chip 200 may further include third and fourth vias 232 and 234 and third and fourth upper connection patterns 252 and 254.

The third vias 232 may be provided to vertically penetrate the second substrate 210 and may be electrically connected to the second semiconductor device 222 of the second semiconductor chip 200. In one or more examples, the third vias 232 may be electrically connected to the semiconductor devices, which are formed on the second substrate 210, and may be used for the vertical interconnection of the semiconductor devices, in the second semiconductor chip 200. The third vias 232 may be disposed on the signal region SR.

The fourth vias 234 may be provided to vertically penetrate the second substrate 210. The fourth vias 234 may be patterns, which are used as an alignment key for placing elements in the second semiconductor chip 200 and for aligning the second semiconductor chip 200 to a third semiconductor chip 300, which will be described below, during the fabrication process of the semiconductor package. In one or more examples, the fourth vias 234 may be arranged to form a specific pattern for the inspection of the horizontal position and rotation of the second semiconductor chip 200 on the dummy region DR. The fourth vias 234 may be electrically disconnected from the second semiconductor device 222. Similar to the second vias 134, top surfaces of the fourth vias 234 may be formed to have a recess region, which is recessed toward the second substrate 210.

The third upper connection patterns 252 may be disposed on the signal region SR. Some of the third upper connection patterns 252 may be connected to the first vias 132. The fourth upper connection patterns 254 may be disposed on the dummy region DR. The fourth upper connection patterns 254 may be provided at the same level as the third upper connection patterns 252. The fourth upper connection patterns 254 may be connected to the fourth vias 234, respectively. The third upper connection patterns 252 and the fourth upper connection patterns 254 may be provided in the second upper passivation layer 260 and may be exposed to a region on a top surface of the second upper passivation layer 260.

The semiconductor package may further include the third semiconductor chip 300 stacked on the second semiconductor chip 200. The third semiconductor chip 300 may have substantially the same or similar structure as the second semiconductor chip 200 described with reference to FIG. 1. For example, the third semiconductor chip 300 may include a third substrate 310, a third semiconductor device 322 formed in the third substrate 310, third lower pads 370, and a third lower passivation layer 380. The second semiconductor chip 200 may not have a via plug and a redistribution layer. However, the present disclosure is not limited to this example.

The third semiconductor device 322 of the third semiconductor chip 300 may be formed near a bottom surface of the third substrate 310 and may be covered with a device interlayer insulating layer. A device interconnection portion, which is connected to the third semiconductor device 322, may be provided in the device interlayer insulating layer. The third semiconductor device 322 may be disposed on the signal region SR. The third lower pads 370 may be disposed below the third substrate 310 and in particular below the device interlayer insulating layer. The third lower pads 370 may be disposed on the signal region SR. The third lower pads 370 may be electrically connected to the third semiconductor device 322. The third lower passivation layer 380 may be disposed below the device interlayer insulating layer. The third lower passivation layer 380 may enclose the third lower pads 370. The third lower pads 370 may be exposed by the passivation layer 380.

The third semiconductor chip 300 may be disposed on the second semiconductor chip 200. The third upper connection patterns 252 of the second semiconductor chip 200 and the third lower pads 370 of the third semiconductor chip 300 may be vertically aligned to each other. The second and third semiconductor chips 200 and 300 may be bonded to each other.

The second semiconductor chip 200 may be connected to the third semiconductor chip 300. In one or more examples, the second semiconductor chip 200 may be in contact with the third semiconductor chip 300. At the interface between the second and third semiconductor chips 200 and 300, the third upper connection patterns 252 of the second semiconductor chip 200 may be bonded to the third lower pads 370 of the third semiconductor chip 300. The third upper connection patterns 252 and the third lower pads 370 may form an inter-metal hybrid bonding structure.

A mold layer 400 may be disposed on the first semiconductor chip 100. The mold layer 400 may be provided on a top surface of the first semiconductor chip 100 to enclose the second and third semiconductor chips 200 and 300. A top surface of the third semiconductor chip 300 may be exposed to the outside near a top surface of the mold layer 400. However, the present disclosure is not limited to this example, and in one or more embodiments, the third semiconductor chip 300 may be buried by the mold layer 400. The mold layer 400 may include a molding material (e.g., an epoxy molding compound (EMC)).

FIG. 10 illustrates an example in which two semiconductor chips 200 and 300 are stacked on the first semiconductor chip 100, but the present disclosure is not limited to this example. In another embodiment, three or more semiconductor chips may be stacked on the first semiconductor chip 100.

FIG. 11 is a sectional view illustrating a semiconductor module according to one or more embodiments of the present disclosure.

Referring to FIG. 11, the semiconductor module may be, for example, a memory module including a module substrate 910, a chip stack package 930 and a graphics processing unit 940 mounted on the module substrate 910, and an outer mold layer 950 covering the chip stack package 930 and the graphics processing unit 940. The semiconductor module may further include an interposer 920 provided on the module substrate 910. In one or more examples, an interposer may be an electrical interface routing between one socket or connection to another. The purpose of an interposer is to spread a connection to a wider pitch or to reroute a connection to a different connection.

The module substrate 910 may be provided. The module substrate 910 may include a printed circuit board (PCB) having signal patterns, which are formed on a top surface thereof.

Module terminals 912 may be disposed below the module substrate 910. The module substrate 910 may include solder balls or solder bumps, and the semiconductor module may be classified into a ball grid array (BGA) type, a fine ball-grid array (FBGA) type, or a land grid array (LGA) type, depending on the kind and structure of the module substrate 910.

The interposer 920 may be provided on the module substrate 910. The interposer 920 may include first substrate pads 922 and second substrate pads 924, which are respectively placed on top and bottom surfaces of the interposer 920 and are exposed to the outside of the interposer 920. The interposer 920 may be configured to provide a redistribution structure for the chip stack package 930 and the graphics processing unit 940. The interposer 920 may be mounted on the module substrate 910 in a flip chip manner. For example, the interposer 920 may be mounted on the module substrate 910 using substrate terminals 926 provided on the second substrate pads 924. The substrate terminals 926 may include solder balls or solder bumps. A first under-fill layer 928 may be provided between the module substrate 910 and the interposer 920.

The chip stack package 930 may be disposed on the interposer 920. The chip stack package 930 may have the same or similar structure as the semiconductor package described with reference to FIGS. 1 to 10. FIG. 11 illustrates an example in which a plurality of second semiconductor chips 200 are provided between the first semiconductor chip 100 and the third semiconductor chip 300, but the present disclosure is not limited to this example. In another embodiment, the chip stack package 930 may be provided to have only the second semiconductor chip 200, like the embodiment of FIG. 10 or to have only two semiconductor chips (e.g., the first and second semiconductor chips 100 and 200), like the embodiment of FIG. 1.

The chip stack package 930 may be mounted on the interposer 920. For example, the chip stack package 930 may be coupled to the first substrate pads 922 of the interposer 920 through the outer terminals 105 of the first semiconductor chip 100. A second under-fill layer 938 may be provided between the chip stack package 930 and the interposer 920. The second under-fill layer 938 may fill a space between the interposer 920 and the first semiconductor chip 100 and may enclose the outer terminals 105 of the first semiconductor chip 100.

The graphics processing unit 940 may be disposed on the interposer 920. The graphics processing unit 940 may be disposed to be spaced apart from the chip stack package 930. The graphics processing unit 940 may be thicker than the semiconductor chips 100, 200, and 300 of the chip stack package 930. The graphics processing unit 940 may include a logic circuit. For example, the graphics processing unit 940 may be a logic chip. Chip terminals 942 may be provided on a bottom surface of the graphics processing unit 940. For example, the graphics processing unit 940 may be coupled to the first substrate pads 922 of the interposer 920 through the chip terminals 942. A third under-fill layer 948 may be provided between the interposer 920 the graphics processing unit 940. The third under-fill layer 948 may fill a space between the interposer 920 and the graphics processing unit 940 and may enclose the chip terminals 942.

The outer mold layer 950 may be provided on the interposer 920. The outer mold layer 950 may cover the top surface of the interposer 920. The outer mold layer 950 may be provided to enclose the chip stack package 930 and the graphics processing unit 940. A top surface of the outer mold layer 950 may be located at the same level as a top surface of the chip stack package 930. The outer mold layer 950 may include an insulating material. For example, the outer mold layer 950 may include an epoxy molding compound (EMC).

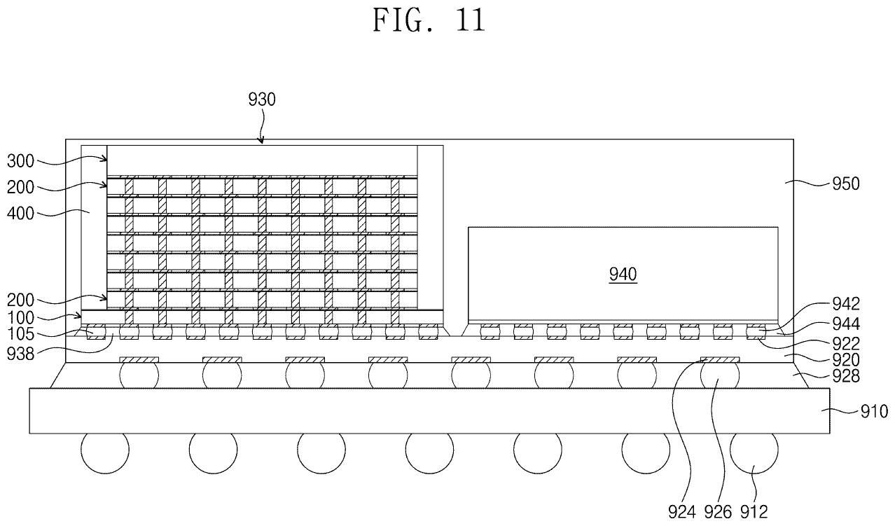

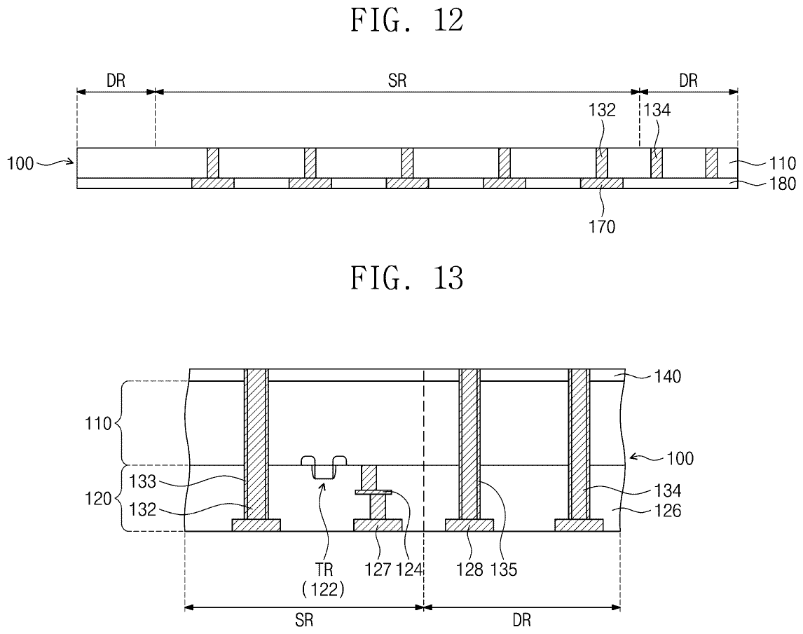

FIGS. 12 to 19 are sectional views illustrating a method of fabricating a semiconductor package, according to one or more embodiments of the present disclosure. FIGS. 13, 15, 17, and 19 are enlarged sectional views illustrating portions of FIGS. 12, 14, 16, and 18.

Referring to FIGS. 12 and 13, the first semiconductor chip 100 may be formed. The first semiconductor chip 100 may be substantially the same or similar as the first semiconductor chip 100 described with reference to FIGS. 1 to 10.

In one or more examples, the first substrate 110 may be provided. The first substrate 110 may be a portion of a semiconductor wafer, which is used to form the first semiconductor chips 100. The first substrate 110 may have the signal region SR and the dummy region DR. The signal region SR may be a region, in which the first semiconductor device 122 and the first device interconnection portion 124 are formed in a subsequent process. The dummy region DR may be a region of a scribe lane, on which a sawing process is performed to separate the first semiconductor chips 100 or the semiconductor packages from each other, after forming the first semiconductor chip 100 on the semiconductor wafer or after forming a semiconductor package, or may be a buffer region between the signal region SR and the scribe lane.

The first circuit layer 120 may be formed by forming a transistor or an integrated circuit on the front surface of the first substrate 110 through a typical process. The first circuit layer 120 may include the first semiconductor device 122 formed on the front surface of the first substrate 110, the first device interlayer insulating layer 126 covering the first semiconductor device 122, the first and second lower connection patterns 127 and 128 exposed to the outside of the first device interlayer insulating layer 126 near the bottom surface of the first device interlayer insulating layer 126, and the first device interconnection portion 124 provided in the first device interlayer insulating layer 126 to connect the first lower connection patterns 127 to the first semiconductor device 122. The first lower connection patterns 127 may be provided on the signal region SR, and the second lower connection patterns 128 may be provided on the dummy region DR. The first insulating layer 140 may be formed by coating or depositing an insulating material on the rear surface of the first substrate 110.

Penetration holes may be formed to penetrate the first substrate 110 and the first insulating layer 140 and to expose the first and second lower connection patterns 127 and 128. A seed layer may be formed to conformally cover the top surface of the first insulating layer 140 and inner side surfaces and bottom surfaces of the penetration holes, and then, a conductive layer may be formed by a plating process using the seed layer. The conductive layer may be formed to fill the penetration holes and to cover the top surface of the first insulating layer 140. A thinning process may be performed on the conductive layer and the seed layer to form the first vias 132, the second vias 134, and the first and second seed layers 133 and 135. The first vias 132, the second vias 134, the first seed layers 133, and the second seed layers 135 may be formed to have top surfaces that are substantially flat and are substantially coplanar with the top surface of the first insulating layer 140.

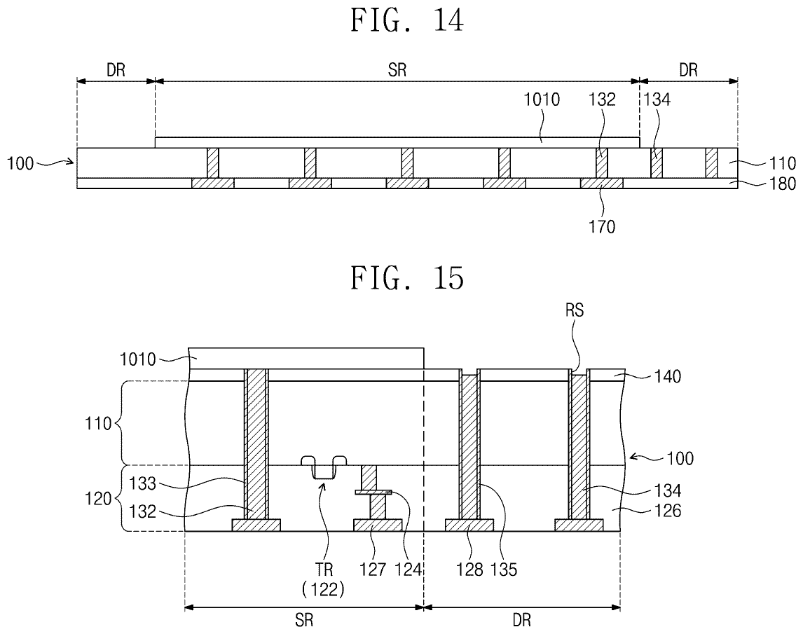

Referring to FIGS. 14 and 15, a mask pattern 1010 may be provided on the first insulating layer 140. The mask pattern 1010 may cover the top surface of the first insulating layer 140. The mask pattern 1010 may be formed to cover the signal region SR and to expose the dummy region DR. The top surfaces of the first vias 132 and the top surfaces of the first seed layers 133 may be veiled by the mask pattern 1010, and the top surfaces of the second vias 134 and the top surfaces of the second seed layers 135 may not be veiled by the mask pattern 1010 and may be exposed.

An etching process may be performed on the second vias 134. The etching process may be a wet etching process. In one or more embodiments, an etching solution, which is used for the etching process, may be used to etch the second vias 134 but may not be used to etch the second seed layers 135 and the first insulating layer 140. As a result of the etching process, the top surfaces of the second vias 134 may be lowered. The top surfaces of the second vias 134 may be located at a vertical level lower than the top surface of the first insulating layer 140. Thus, the recess regions RS, which are enclosed by the top surfaces of the second vias 134 and the second seed layers 135, may be formed. The recess regions RS may be used as an alignment key, which is formed in an intaglio manner. For example, in one or more examples, during the fabrication process, an image of the region RS may be taken to serve as an alignment reference.

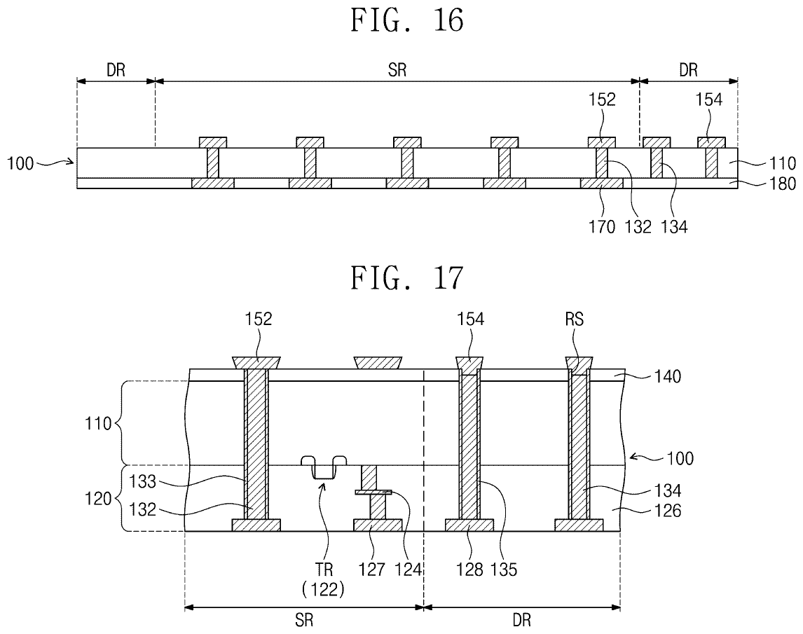

Referring to FIGS. 16 and 17, the mask pattern 1010 may be removed. Thus, the top surface of the first insulating layer 140 and the top surfaces of the first vias 132 may be exposed.

The first and second upper connection patterns 152 and 154 may be formed on the first insulating layer 140. For example, the first and second upper connection patterns 152 and 154 may be formed by forming a conductive layer on the first insulating layer 140 and patterning the conductive layer. The first upper connection patterns 152 may be connected to the first vias 132, and the second upper connection patterns 154 may be connected to the second vias 134.

The second vias 134 or the recess regions RS on the second vias 134 may be used as the alignment key in a process of patterning the conductive layer. For example, due to the placement of the second vias 134 or the recess regions RS, planar coordinates on the first substrate 110 may be defined. A region of the conductive layer, which is patterned, or a position of the mask pattern, which is used to etch the conductive layer, may be determined based on the planar coordinates.

In one or more embodiments, since the second vias 134 and the recess regions RS, which are formed during the process of forming the first vias 132, are used as the alignment key, an additional process may not be required to form the alignment key. The second vias 134 and the recess regions RS may form an intaglio alignment key, and this may improve the visibility or sensitivity of the alignment key during the alignment process. In one or more examples, it may be possible to simplify a process of fabricating a semiconductor package or to reduce a process error in the fabrication process.

In another embodiment, depending on the shape of the recess regions RS, the conductive layer, which is deposited on the first insulating layer 140, may have a recessed portion, on the recess region RS. In one or more examples, a top surface of the conductive layer may have a concave surface in an upper portion of the recess region RS. The recessed portion may be used as the alignment key in a process after forming the first and second upper connection patterns 152 and 154. In this case, the semiconductor package described with reference to FIG. 4 may be fabricated. Hereinafter, the present disclosure will be described with reference to the embodiment of FIG. 1.

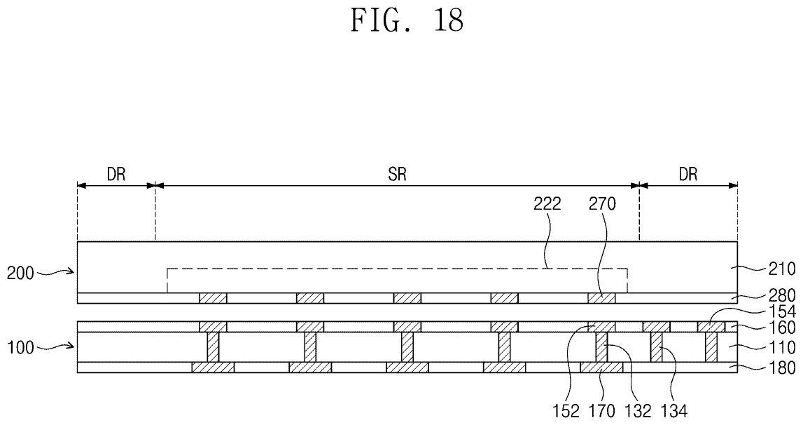

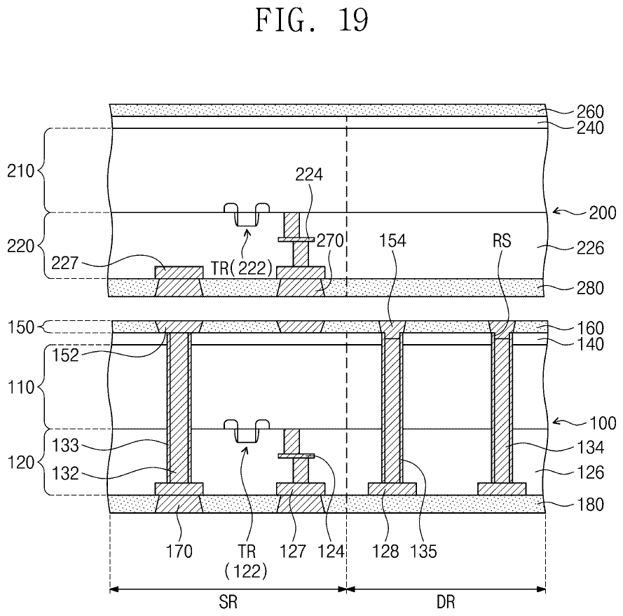

Referring to FIGS. 18 and 19, the first upper passivation layer 160 may be formed on the first insulating layer 140. For example, an insulating layer may be formed on the first insulating layer 140 to cover the first and second upper connection patterns 152 and 154, and a thinning process may be performed on the insulating layer to form the first upper passivation layer 160. The top surfaces of the first and second upper connection patterns 152 and 154 may be exposed to the outside of the first upper passivation layer 160 near the top surface of the first upper passivation layer 160.

FIGS. 16 to 19 illustrate an example in which the first and second upper connection patterns 152 and 154 are formed before the forming of the first upper passivation layer 160, but the present disclosure is not limited to this example. In another embodiment, the first upper passivation layer 160 may be formed to cover the first insulating layer 140, openings may be formed in the first upper passivation layer 160 to expose the first vias 132 and the second vias 134, and the first and second upper connection patterns 152 and 154 may be formed by filling the openings with a conductive material.

Referring further to FIGS. 18 and 19, the first lower pads 170 and the first lower passivation layer 180 may be formed on the front surface of the first substrate 110. For example, the first lower passivation layer 180 may be formed to cover the bottom surface of the first device interlayer insulating layer 126, openings may be formed in the first lower passivation layer 180 to expose the first lower connection patterns 127, and the first lower pads 170 may be formed by filling the openings with a conductive material.

The second semiconductor chip 200 may be formed. The second semiconductor chip 200 may be substantially the same or similar as the second semiconductor chip 200 described with reference to FIGS. 1 to 10. For example, the second semiconductor chip 200 may include the second substrate 210, the second circuit layer 220, the second lower pads 270, and the second lower passivation layer 280.

In one or more examples, the second substrate 210 may be provided. The second substrate 210 may be a portion of a semiconductor wafer, on which a plurality of second semiconductor chips 200 are formed.

The second circuit layer 220 may be formed by forming a transistor or an integrated circuit on the front surface of the second substrate 210 through a typical process. The second circuit layer 220 may include the second semiconductor device 222 formed on the front surface of the second substrate 210, the second device interlayer insulating layer 226 covering the second semiconductor device 222, the third lower connection patterns 227 exposed to the outside of the second device interlayer insulating layer 226 near the bottom surface of the second device interlayer insulating layer 226, and the second device interconnection portion 224, which is formed in the second device interlayer insulating layer 226 to connect the third lower connection patterns 227 to the second semiconductor device 222. The third lower connection patterns 227 may be provided on the signal region SR. The second insulating layer 240 may be formed by coating or depositing an insulating material on a rear surface of the second substrate 210. The second upper passivation layer 260 may be formed on the second insulating layer 240. The second lower pads 270 and the second lower passivation layer 280 may be formed on the bottom surface of the second device interlayer insulating layer 226.

Referring back to FIGS. 1 and 2, the second semiconductor chip 200 may be bonded to the first semiconductor chip 100. The first and second semiconductor chips 100 and 200 may be bonded to each other in a wafer-to-wafer manner or a chip-to-wafer manner. The second semiconductor chip 200 may be disposed on the first semiconductor chip 100. For example, the active surface of the second semiconductor chip 200 may face the inactive surface of the first semiconductor chip 100. The second semiconductor chip 200 may be disposed on the first semiconductor chip 100 in such a way that the second lower pads 270 of the second semiconductor chip 200 are vertically aligned to the first upper connection patterns 152 of the first semiconductor chip 100.

A thermal treatment process may be performed on the first and second semiconductor chips 100 and 200. The first upper connection patterns 152 and the second lower pads 270 may be bonded to each other by the thermal treatment process. For example, the first upper connection patterns 152 may be bonded to the second lower pads 270 to form a single object. The bonding of the first upper connection patterns 152 and the second lower pads 270 may be naturally performed. In one or more examples, the first upper connection patterns 152 and the second lower pads 270 may be formed of the same material (e.g., copper (Cu)), and in this case, they may be bonded to each other by an inter-metal hybrid bonding process caused by a surface activation phenomenon at an interface therebetween. In another embodiment, the second lower passivation layer 280 may be bonded to the first upper passivation layer 160 by the thermal treatment process. In order to facilitate the bonding process of the first and second semiconductor chips 100 and 200, the second semiconductor chip 200 may be closely attached to the first semiconductor chip 100. For example, a bonding tool may be used to compress the second semiconductor chip 200 toward the first semiconductor chip 100.

In another embodiment, as shown in FIGS. 7 and 8, the second semiconductor chip 200 may be mounted on the first semiconductor chip 100 using the intermediate connection terminals 205.

Next, the outer terminals 105 may be provided on the first lower pads 170.

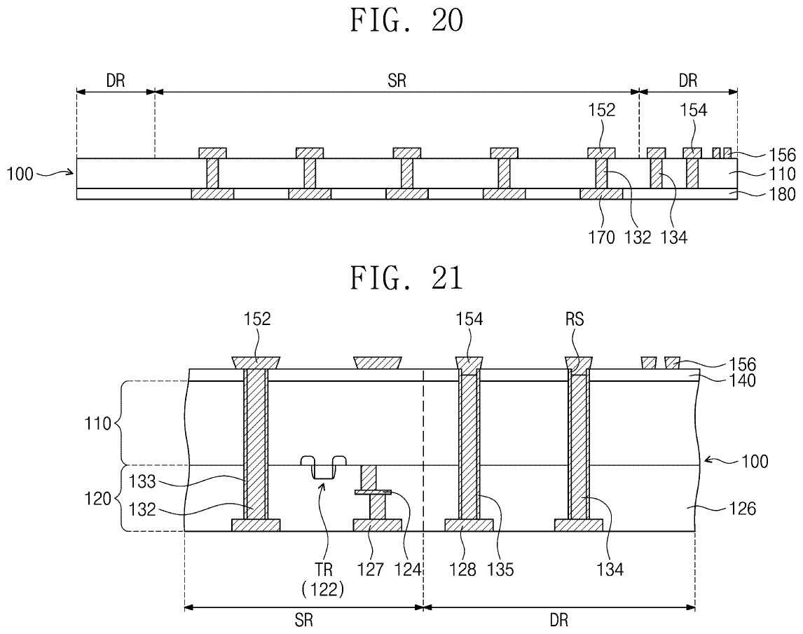

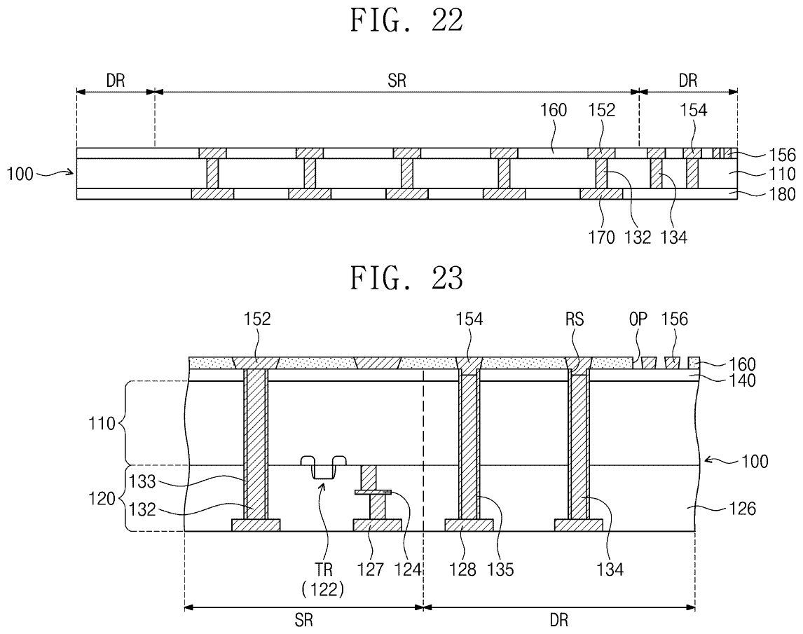

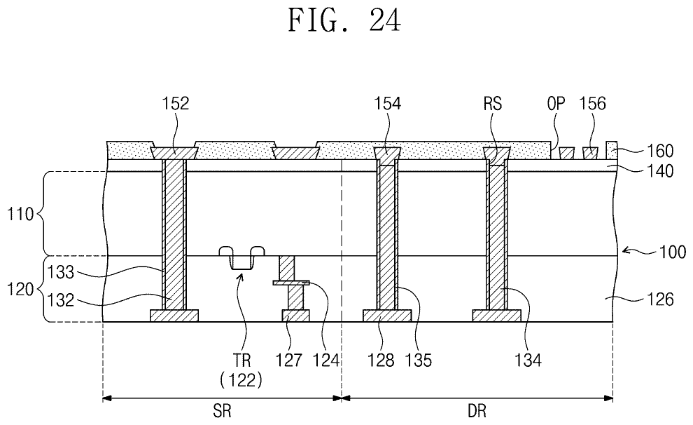

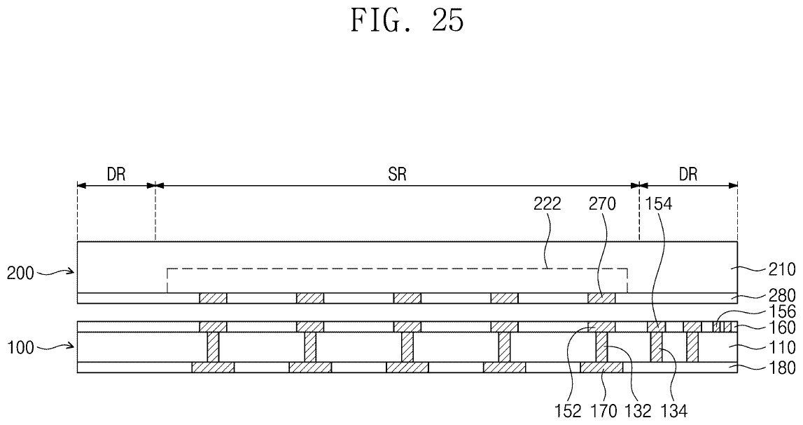

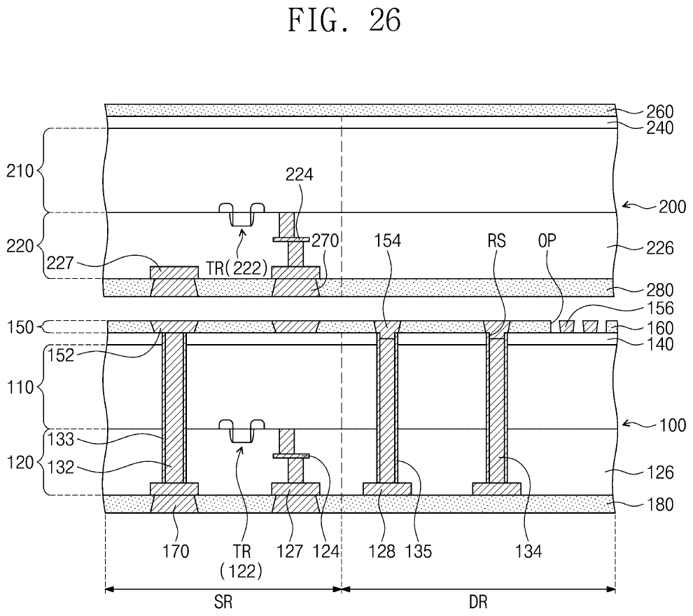

FIGS. 20 to 26 are diagrams illustrating a method of fabricating a semiconductor package, according to one or more embodiments of the present disclosure. FIG. 21 is an enlarged sectional view illustrating a portion of FIG. 20, FIGS. 23 and 24 are enlarged sectional views illustrating a portion of FIG. 22, and FIG. 26 is an enlarged sectional view illustrating a portion of FIG. 25.

Referring to FIGS. 20 and 21, the mask pattern 1010 may be removed from the structure of FIG. 15. Accordingly, the top surface of the first insulating layer 140 and the top surfaces of the first vias 132 may be exposed.

The first to third upper connection patterns 152, 154, and 156 may be formed on the first insulating layer 140. For example, a conductive layer may be formed on the first insulating layer 140 and may be patterned to form the first to third upper connection patterns 152, 154, and 156. The first upper connection patterns 152 may be connected to the first vias 132, and the second upper connection patterns 154 may be connected to the second vias 134. The third upper connection patterns 156 may be formed on the dummy region DR to be spaced apart from the second upper connection patterns 154.

Referring to FIGS. 22 and 23, the first upper passivation layer 160 may be formed on the first insulating layer 140. For example, an insulating layer may be formed on the first insulating layer 140 to cover the first to third upper connection patterns 152, 154, and 156, and then, a thinning process may be performed on the insulating layer to form the first upper passivation layer 160. The top surfaces of the first to third upper connection patterns 152, 154, and 156 may be exposed to a region on the top surface of the first upper passivation layer 160.

Next, the first upper passivation layer 160 may be patterned to form the opening OP exposing the third upper connection patterns 156. The third upper connection patterns 156 may be placed within the opening OP.

In another embodiment, the first upper passivation layer 160 may be formed in such a way that the second upper connection patterns 154 are not exposed to the outside. Referring to FIGS. 22 and 24, the first upper passivation layer 160 may be formed on the first insulating layer 140. For example, the first upper passivation layer 160 may be formed by forming an insulating layer on the first insulating layer 140 to cover the first to third upper connection patterns 152, 154, and 156. The first to third upper connection patterns 152, 154, and 156 may be buried by the first upper passivation layer 160.

Thereafter, the first upper passivation layer 160 may be patterned to form recesses exposing the first upper connection patterns 152 and the opening OP exposing the third upper connection patterns 156. The third upper connection patterns 156 may be placed within the opening OP. In this case, the semiconductor package may be fabricated to have the structure described with reference to FIG. 9.

Referring to FIGS. 25 and 26, the first lower pads 170 and the first lower passivation layer 180 may be formed on the front surface of the first substrate 110.

The second semiconductor chip 200 may be formed. The second semiconductor chip 200 may be formed using substantially the same or similar method as described with reference to FIGS. 18 and 19.

Referring back to FIGS. 5 and 6, the second semiconductor chip 200 may be bonded to the first semiconductor chip 100. The first and second semiconductor chips 100 and 200 may be bonded to each other in a wafer-to-wafer manner or in a chip-to-wafer manner. A thermal treatment process may be performed on the first and second semiconductor chips 100 and 200. As a result of the thermal treatment process, the first upper connection patterns 152 and the second lower pads 270 may be bonded to each other.

The third upper connection patterns 156 may be used as an alignment key in a process of mounting the second semiconductor chip 200 on the first semiconductor chip 100. For example, planar coordinates on the first substrate 110 may be defined, due to the placement of the third upper connection patterns 156. The position of the second semiconductor chip 200 may be determined, based on the planar coordinates.

In one or more embodiments, even when the second upper connection patterns 154 are veiled by the first upper passivation layer 160 after a back-end process of forming the first and second upper connection patterns 152 and 154, the third upper connection patterns 156 may be used as the alignment key. In addition, the third upper connection patterns 156 may be formed when the first and second upper connection patterns 152 and 154 are formed, and the opening OP exposing the third upper connection patterns 156 may be formed during the process of patterning the first upper passivation layer 160. Thus, an additional process may not be required to form the alignment key, and this may make it possible to simplify a process of fabricating a semiconductor package or to reduce a process error in the fabrication process.

In another embodiment, the second semiconductor chip 200 may be mounted on the first semiconductor chip 100 using the intermediate connection terminals 205, as shown in FIG. 9.

Next, the outer terminals 105 may be provided on the first lower pads 170.

In a semiconductor package according to one or more embodiments of the present disclosure, second vias, which are formed during a process of forming first vias for signal transmission, may be used as an alignment key, and thus, an additional process for forming the alignment key may not be required. Furthermore, the second vias may form an intaglio alignment key whose top surface is located at a lowered level, and this may improve the visibility or sensitivity of the alignment key in an alignment process. Second upper connection patterns, which are formed during a process of forming first upper connection patterns for signal transmission, may be used as an alignment key, and in this case, an additional process for forming the alignment key may not be required. In addition, even when the second vias are veiled in a subsequent process after the formation of the second vias, the second upper connection patterns may be used as the alignment key. As a result, it may be possible to simplify a process of fabricating a semiconductor package and to reduce a process error in the fabrication process.

While example embodiments of the present disclosure have been particularly shown and described, it will be understood by one of ordinary skill in the art that variations in form and detail may be made therein without departing from the spirit and scope of the attached claims.

What is claimed is:

1. A semiconductor package, comprising:
a first semiconductor chip; and
a second semiconductor chip on the first semiconductor chip,
wherein the first semiconductor chip comprises:
a first substrate,
a first semiconductor device provided on a first surface of the first substrate,
a first interconnection layer on the first surface of the first substrate,
an insulating layer covering a second surface of the first substrate that is opposite to the first surface of the first substrate,
a first via and a second via penetrating the first substrate and the insulating layer in a first direction that is perpendicular to the first surface of the first substrate, and
a connection pattern on a surface of the insulating layer and connected to the first via and the second via,
wherein a surface of the first via is coplanar with the surface of the insulating layer, and
wherein a surface of the second via is located at a level lower than the surface of the insulating layer.

2. The semiconductor package of claim 1, wherein the connection pattern comprises a first pattern connected to the first via and a second pattern connected to the second via, and
wherein the second pattern comprises a protruding portion, which is extended into the insulating layer and is in contact with the surface of the second via.

3. The semiconductor package of claim 2, wherein the first pattern is in contact with the surface of the first via, and
a surface of the first pattern is substantially flat.

4. The semiconductor package of claim 2, wherein the first semiconductor chip further comprises a signal region and a dummy region enclosing the signal region,
wherein the connection pattern further comprises an alignment pattern,
wherein the first pattern is on the signal region, and
wherein the second pattern and the alignment pattern are on the dummy region.

5. The semiconductor package of claim 4, wherein the insulating layer is between the alignment pattern and the first substrate.

6. The semiconductor package of claim 4, wherein the first semiconductor chip further comprises a passivation layer, which is provided on the surface of the insulating layer such that the passivation layer covers at least a portion of the connection pattern,
wherein the passivation layer has an opening exposing the alignment pattern, and
wherein the alignment pattern is spaced apart from an inner side surface of the opening.

7. The semiconductor package of claim 6, wherein the alignment pattern is disconnected from the first semiconductor device,
wherein the alignment pattern is located at a same level as the first pattern and the second pattern, and
wherein the passivation layer covers at least a portion of the second pattern.

8. The semiconductor package of claim 1, wherein the first semiconductor chip further comprises a signal region and a dummy region enclosing the signal region,
wherein the first via is on the signal region,
wherein the first via is connected to the first semiconductor device,
wherein the second via is on the dummy region, and
wherein the second via is disconnected from the first semiconductor device.

9. The semiconductor package of claim 1, wherein the first semiconductor chip further comprises a seed layer enclosing an outer circumferential surface of the second via, and
wherein an end of the seed layer is located at a level higher than an end of the second via.

10. The semiconductor package of claim 1, wherein the second semiconductor chip comprises:
a second substrate,
a second semiconductor device on a surface of the second substrate, and
a second interconnection layer on the surface of the second substrate,
wherein the second interconnection layer is mounted on the connection pattern using a connection terminal.

11. A semiconductor package, comprising:
a first semiconductor chip; and
a second semiconductor chip on the first semiconductor chip,
wherein the first semiconductor chip comprises:
a substrate,
a semiconductor device provided on a first surface of the substrate,
an interconnection layer on the first surface of the substrate,
an insulating layer covering a second surface of the substrate that is opposite to the first surface of the substrate;
a first via penetrating the substrate and the insulating layer in a first direction that is perpendicular to the first surface of the substrate,
a connection pattern on a surface of the insulating layer and connected to the first via, and
a passivation layer on the surface of the insulating layer to such that the passivation layer covers at least a portion of the connection pattern,
wherein a surface of the first via is placed at a level lower than the surface of the insulating layer,
wherein the first semiconductor chip further comprises a signal region and a dummy region enclosing the signal region, and
wherein the connection pattern comprises:
a first pattern connected to the first via, and
an alignment pattern on the dummy region,
the alignment pattern is disconnected from the semiconductor device, and
the alignment pattern is placed at a same level as the first pattern.

12. The semiconductor package of claim 11, wherein the first semiconductor chip further comprises a second via, which is disposed on the signal region to penetrate the substrate and the insulating layer in the first direction,
wherein the second via is electrically connected to the semiconductor device,
wherein the connection pattern further comprises a second pattern connected to the second via, and
wherein the surface of the second via is coplanar with the surface of the insulating layer.

13. The semiconductor package of claim 12, wherein the second pattern is in contact with the surface of the second via, and
a surface of the second pattern is substantially flat.

14. The semiconductor package of claim 11, wherein the first via is on the dummy region, and
wherein the passivation layer covers at least a portion of the first pattern.

15. The semiconductor package of claim 11, wherein the first pattern comprises a protruding portion, which is extended into the insulating layer and is in contact with the surface of the first via.

16. The semiconductor package of claim 11, wherein the insulating layer is between the alignment pattern and the substrate.

17. The semiconductor package of claim 11, wherein the passivation layer has an opening exposing the alignment pattern, and
the alignment pattern is spaced apart from an inner side surface of the opening.

18. The semiconductor package of claim 11, wherein the first semiconductor chip further comprises a seed layer enclosing an outer circumferential surface of the first via, and
wherein an end of the seed layer is located at a level higher than an end of the first via.

19. A semiconductor package, comprising:
a first semiconductor chip; and
a second semiconductor chip on the first semiconductor chip,
wherein the first semiconductor chip comprises:
a substrate,
a semiconductor device on a first surface of the substrate,
an interconnection layer on the first surface of the substrate,
an insulating layer covering at least a portion of a second surface of the substrate that is opposite to the first surface of the substrate,
a first via and a second via penetrating the substrate and the insulating layer in a first direction that is perpendicular to the first surface of the substrate,
a connection pattern on a surface of the insulating layer, the connection pattern comprising a first pattern connected to the first via and a second pattern connected to the second via, and
a passivation layer on the surface of the insulating layer to cover the second pattern and to expose the first pattern,
wherein the first via is connected to the semiconductor device,
wherein the second via is disconnected from the semiconductor device, and
wherein a surface of the second via is located at a level lower than a surface of the insulating layer.

20. The semiconductor package of claim 19, wherein a surface of the first via is coplanar with the surface of the insulating layer, and
the second pattern comprises a protruding portion, which is extended into the insulating layer and is in contact with the surface of the second via.
